(19) United States
(12) Patent Application Publication
(10) Pub. No.: US 2024/0429152 A1
(43) Pub. Date: Dec. 26, 2024

(54) SEMICONDUCTOR DEVICE

(71) Applicant: FUJI ELECTRIC CO., LTD., Kawasaki-shi (JP)

(72) Inventor: Takashi KATSUKI, Matsumoto-city (JP)

(73) Assignee: FUJI ELECTRIC CO., LTD., Kawasaki-shi (JP)

(21) Appl. No.: 18/641,616

(22) Filed: Apr. 22, 2024

(30) Foreign Application Priority Data
Jun. 21, 2023 (JP) 2023-101304

(51) Int. Cl. H01L 23/498; H01L 23/00; H01L 23/31; H01L 25/07; H01L 25/18

(52) U.S. Cl. CPC H01L 23/49838; H01L 23/3107; H01L 23/49811; H01L 25/072; H01L 25/18; H01L 24/32; H01L 24/48; H01L 24/73; H01L 2224/32225; H01L 2224/48155; H01L 2224/73265; H01L 2924/13055

(57) ABSTRACT

A semiconductor device includes: an insulated circuit board including an insulating plate and a conductive layer provided on a top surface side of the insulating plate; a semiconductor chip provided on a top surface side of the conductive layer; a sealing resin sealing the semiconductor chip; and an external terminal electrically connected to the semiconductor chip and having a lower portion embedded in the sealing resin and an upper portion projecting above a top surface of the sealing resin.

### CROSS-REFERENCE TO RELATED APPLICATION

This application claims benefit of priority under 35 USC 119 based on Japanese Patent Application No. 2023-101304 filed on Jun. 21, 2023, the entire contents of which are incorporated by reference herein.

### BACKGROUND OF THE INVENTION

### 1. Field of the Invention

This disclosure relates to a semiconductor device.

### 2. Description of the Related Art

JP2013-062407A discloses a configuration in which a circuit pattern portion formed on a top surface side of a base substrate and a terminal member attached onto the circuit pattern portion and electrically connected to a semiconductor chip via the circuit pattern portion are provided, and the terminal member is formed in a tubular shape having an upper end surface exposed to an outer surface of molding resin and having a threaded hole open on the upper end surface. JP2007-184315A discloses a configuration in which a threaded hole is provided in a main terminal and the threaded hole is exposed on a top surface of sealing resin.

JPH09-321216A discloses a configuration in which a nut is attached and fixed by soldering to a base conductive layer and a lead terminal electrode layer that are electrically connected to a semiconductor chip, and the nut functions as an external lead terminal. JP2022-160270A discloses a configuration in which a terminal block fixed to a circuit board on a base plate and having a threaded hold for bolt fastening is provided. JP2002-314038A discloses a configuration in which a bus bar is fastened by a screw to an emitter terminal disposed on a substrate.

JP2009-130163A discloses a configuration in which a heat spreader having a threaded hole is provided on a semiconductor element, and a wiring terminal is electrically and thermally connected to the heat spreader by screwing with a screw. WO2020/105476A1 discloses a configuration in which a spacer is provided between a conductive substrate and each of an input terminal and an output terminal. JP2021-144984A discloses a configuration in which a terminal is put on a top surface of a block on a circuit board and welded by laser.

WO2009/081723A1 discloses a configuration in which a connecting conductor is fixed to a copper foil formed on a ceramic, resin is filled below a top surface of the connecting conductor and welded by laser, and after that, resin is filled.

JP2015-130456A discloses a configuration in which a first main terminal and a second main terminal joined to a semiconductor chip are provided, and the first main terminal and the second main terminal penetrate through sealing resin to be exposed outside the sealing resin.

A conventional power semiconductor module is hard to be downsized because an external terminal for connecting a semiconductor chip to an external circuit has a long wiring length.

### SUMMARY OF THE INVENTION

In view of the above problem, an object of this disclosure is to provide a semiconductor device which can shorten the wiring length of an external terminal and which can be downsized.

An aspect of the present invention inheres in a semiconductor device including: an insulated circuit board including an insulating plate and a conductive layer provided on a top surface side of the insulating plate; a semiconductor chip provided on a top surface side of the conductive layer; a sealing resin sealing the semiconductor chip; a case provided to surround an outer periphery of the sealing resin and placing above the top surface of the sealing resin; and an external terminal electrically connected to the semiconductor chip and having a lower portion embedded in the sealing resin and an upper portion projecting above a top surface of the sealing resin and a top surface of the case.

### BRIEF DESCRIPTION OF THE DRAWINGS

FIG. 1 is a cross-sectional view illustrating an example of a semiconductor device according to a first embodiment;

FIG. 2 is a cross-sectional view illustrating a region A in FIG. 1 in an enlarged manner;

FIG. 3 is a process cross-sectional view of a manufacturing method of the semiconductor device according to the first embodiment;

FIG. 4 is a process cross-sectional view of the manufacturing method of the semiconductor device according to the first embodiment, subsequent to FIG. 3;

FIG. 5 is a process cross-sectional view of the manufacturing method of the semiconductor device according to the first embodiment, subsequent to FIG. 4;

FIG. 6 is a process cross-sectional view of the manufacturing method of the semiconductor device according to the first embodiment, subsequent to FIG. 5;

FIG. 7 is a process cross-sectional view of the manufacturing method of the semiconductor device according to the first embodiment, subsequent to FIG. 6;

FIG. 8 is a process cross-sectional view of the manufacturing method of the semiconductor device according to the first embodiment, subsequent to FIG. 7;

FIG. 9 is a cross-sectional view illustrating a semiconductor device according to a first comparative example;

FIG. 10 is a cross-sectional view illustrating a semiconductor device according to a second comparative example;

FIG. 11 is a cross-sectional view illustrating an example of a semiconductor device according to a second embodiment;

FIG. 12 is a cross-sectional view illustrating an example of a semiconductor device according to a third embodiment;

FIG. 13 is a cross-sectional view illustrating an example of a semiconductor device according to a fourth embodiment;

FIG. 14 is a cross-sectional view illustrating an example of a semiconductor device according to a fifth embodiment;

FIG. 15 is a cross-sectional view illustrating an example of a semiconductor device according to a sixth embodiment;

FIG. 16 is a plan view illustrating an example of a semiconductor device according to a seventh embodiment;

FIG. 17 is a plan view illustrating the semiconductor device according to the seventh embodiment without a case;

FIG. 18 is a plan view of the case of the semiconductor device according to the seventh embodiment;

FIG. 19 is a cross-sectional view taken along a direction of A-A in FIG. 16;

FIG. 20 is a cross-sectional view taken along a direction of B-B in FIG. 16; and

FIG. 21 is a circuit diagram illustrating an equivalent circuit of the semiconductor device according to the seventh embodiment.

### DETAILED DESCRIPTION

With reference to the drawings, first to seventh embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Moreover, in some drawings, portions are illustrated with different dimensional relationships and proportions. The first to seventh embodiments described below merely illustrate schematically devices and methods for specifying and giving shapes to the technical idea of the present invention, and the span of the technical idea is not limited to materials, shapes, structures, and relative positions of elements described herein.

Additionally, definitions of directions such as “upper and lower” and “left and right” in the following description are simply definitions for convenience of description, and do not limit the technological concept of the present invention. For example, when observing an object rotated by 90 degrees, the “upper and lower” is converted to “left and right” to be read, and when observing an object rotated by 180 degrees, the “upper and lower” are read reversed, which should go without saying.

In the following description, a “first main electrode” of a semiconductor chip means an electrode through which a main current flows into or flows out of the semiconductor chip. The “first main electrode” is assigned to any one of a source electrode or a drain electrode when the semiconductor chip implements a field-effect transistor (FET) or a static induction transistor (SIT). The “first main electrode” is assigned to any one of an emitter electrode or a collector electrode when the semiconductor chip implements an insulated-gate bipolar transistor (IGBT). The “first main electrode” is assigned to any one of an anode electrode or a cathode electrode when the semiconductor chip implements a static induction (SI) thyristor or a gate turn-off (GTO) thyristor. A “second main electrode” of the semiconductor chip is assigned to any one of the source electrode or the drain electrode, which is not assigned as the first main electrode, when the semiconductor chip implements the FET or the SIT. The “second main electrode” is assigned to any one of the emitter electrode or the collector electrode, which is not assigned as the first main electrode, when the semiconductor chip implements the IGBT. The “second main electrode” is assigned to any one of the anode electrode or the cathode electrode, which is not assigned as the first main electrode, when the semiconductor chip implement the SI thyristor or the GTO thyristor. That is, when the “first main electrode” is the source electrode, the “second main electrode” means the drain electrode. When the “first main electrode” is the emitter electrode, the “second main electrode” means the collector electrode. When the “first main electrode” is the anode electrode, the “second main electrode” means the cathode electrode.

### First Embodiment

### <Circuitry of Semiconductor Device>

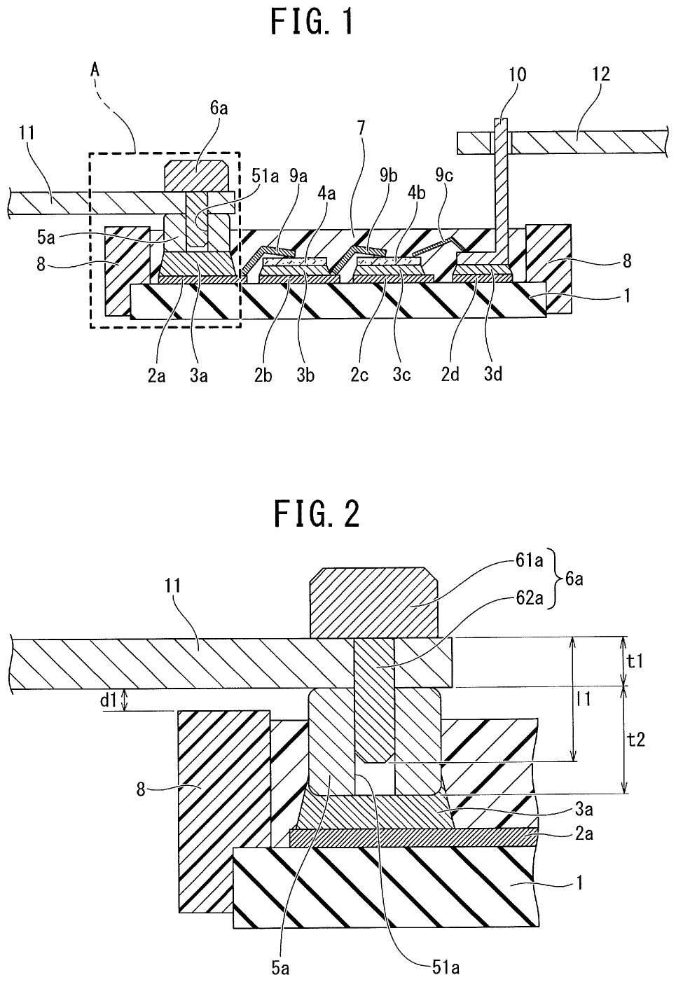

FIG. 1 illustrates a state where a semiconductor device according to a first embodiment is used. As illustrated in FIG. 1, the semiconductor device according to the first embodiment includes an insulated circuit board (1, 2a to 2d). The insulated circuit board (1, 2a to 2d) includes an insulating plate 1 and conductive layers 2a to 2d provided on the top surface side of the insulating plate 1.

The insulating plate 1 is constituted by a resin insulating layer using a polymeric material, or a ceramics plate containing, as a base compound, aluminum oxide (Al₂O₃), aluminum nitride (AlN), silicon nitride (Si₃N₄), boron nitride (BN), or the like, for example.

The conductive layers 2a to 2d are made of metal such as copper (Cu) or aluminum (Al), for example. Respective plane patterns of the conductive layers 2a to 2d, the number of conductive layers 2a to 2d, respective arrangement positions of the conductive layers 2a to 2d, and so on are not particularly limited.

The insulated circuit board (1, 2a to 2d) may further include a conductive layer provided on the bottom surface side of the insulating plate 1. The insulated circuit boards (1, 2a to 2d) may be, for example, a direct copper bonding (DCB) substrate, an active metal brazing (AMB) substrate, or the like.

Although not illustrated herein, a cooling plate (base) or a cooling fin may be provided on the bottom surface side of the insulated circuit board (1, 2a to 2d) via a bonding layer made of solder, a sintered material, a thermal compound, or the like. The cooling plate or the cooling fin may be made of copper (Cu), aluminum (Al), a composite material (AlSiC) of Al and silicon carbide, a composite material (MgSiC) of magnesium (Mg) and silicon carbide, or the like, for example.

A nut 5a is provided on the top surface side of the conductive layer 2a via a bonding layer 3a. The nut 5a is electrically connected to semiconductor chips 4a and 4b. The nut 5a has a function as an external terminal for electrically connecting the semiconductor chips 4a and 4b to an external circuit. It is preferable that the nut 5a be made of a material having a high conductivity. The nut 5a is made of metal such as copper (Cu), Cu alloy, aluminum (Al), or Al alloy, for example.

A screw (bolt) 6a penetrates through a through-hole for a main wiring 11 as an external element and is fastened with the nut 5a. A fastening portion (5a, 6a) is constituted by the nut 5a and the screw 6a, and the nut 5a serves as part of the fastening portion (5a, 6a). The main wiring 11 is connected to an external circuit such as a capacitor. When the screw 6a is fastened with the nut 5a, the main wiring 11 is fixed. The semiconductor device according to the first embodiment may include the screw 6a as a constituent, or the screw 6a may be provided as an external element.

The semiconductor chip 4a as a semiconductor element for a power semiconductor element is provided on the top surface side of the conductive layer 2b via a bonding layer 3b. The semiconductor chip 4b is provided on the top surface side of the conductive layer 2c via a bonding layer 3c.

Herein, a case where the semiconductor chip 4a and 4b is constituted by a reverse conducting insulated gate bipolar transistor (RC-IGBT) will be described. Note that the semiconductor chip 4a and 4b may be constituted by a combination of a metal-oxide-semiconductor field-effect transistor (MOSFET), a static induction (SI) thyristor or a gate turnoff (GTO) thyristor, and a diode. The semiconductor chip 4a and 4b is constituted by a semiconductor substrate made of silicon (Si), silicon carbide (SiC), gallium nitride (GaN), gallium oxide (Ga₂O₃), diamond (C), or the like, for example. The arrangement position of the semiconductor chip 4a and 4b, the number of semiconductor chips 4a and 4b, and the type of the semiconductor chip 4a and 4b are not limited particularly.

The semiconductor chip 4a and 4b includes a collector electrode (not illustrated) as a first main electrode provided on the bottom surface side, and an emitter electrode (not illustrated) as second main electrode and a gate electrode (not illustrated) provided on the top surface side. The conductive layer 2b is joined to the collector electrode on the bottom surface side of the semiconductor chip 4a via the bonding layer 3b. The conductive layer 2c is joined to the collector electrode on the bottom surface side of the semiconductor chip 4b via the bonding layer 3c.

A control terminal 10 is provided on the top surface side of the conductive layer 2d via a bonding layer 3d. The control terminal 10 is made of metal such as copper (Cu), Cu alloy, aluminum (Al), or Al alloy, for example. A printed circuit board (PCB) 12 is fixed to the control terminal 10 by soldering, press-fitting, or the like. At the time of operation of the semiconductor device according to the first embodiment, a control signal supplied from the printed circuit board 12 is applied to the gate electrodes of the semiconductor chips 4a and 4b via the control terminal 10, so that ON/OFF operation on the semiconductor chips 4a and 4b is controlled.

The bonding layers 3a to 3d are each made of, for example, solder, a conductive adhesive, a sintered material, or the like. The solder usable herein is, for example, lead-free solder such as tin-antimony (Sn—Sb) based solder, tin-copper (Sn—Cu) based solder, tin-copper-silver (Sn—Cu—Ag) based solder, tin-silver (Sn—Ag) based solder, tin-silver-copper (Sn—Ag—Cu) based solder, tin-silver-bismuth-copper (Sn—Ag—Bi—Cu) based solder, tin-indium-silver-bismuth (Sn—In—Ag—Bi) based solder, tin-zinc (Sn—Zn) based soler, tin-zinc-bismuth (Sn—Zn—Bi) based solder, tin-bismuth (Sn—Bi) based solder, or tin-indium (Sn—In) based solder, or lead solder such as tin-lead (Sn—Pb) based solder. The conductive adhesive usable herein is an adhesive obtained by mixing metal particles of silver (Ag) or the like into resin such as epoxy resin, for example. The sintered material is obtained, for example, such that a sheet-shaped sintering sheet or a paste-form conductive paste containing an organic component (binder) and metal particles of gold (Au), silver (Ag), copper (Cu), or the like with a minute particle diameter of around a few nanometers to a few micrometers is pressurized and sintered while the sintering sheet or the conductive paste is heated.

The bonding layers 3a to 3d may be made of the same material or may be made of respective materials different from each other. The bonding layers 3a to 3d may have generally the same thickness or may have respective thicknesses different from each other. FIG. 1 illustrates a case where the thickness of the bonding layer 3a is thicker than the thicknesses of the bonding layers 3b to 3d.

FIG. 1 illustrates a case where bonding wires 9a to 9c are connected to the top surface sides of the semiconductor chips 4a and 4b, but this is just an example, and electric connection relationships on the top surface sides of the semiconductor chips 4a and 4b are not limited to this. The emitter electrode on the top surface side of the semiconductor chip 4a is electrically connected to the conductive layer 2a via a connection member such as the bonding wire 9a. The emitter electrode on the top surface side of the semiconductor chip 4b is electrically connected to the conductive layer 2b via a connection member such as the bonding wire 9b. The gate electrode on the top surface side of the semiconductor chip 4a is electrically connected to the control terminal 10 via a connection member (not illustrated) such as a bonding wire. The gate electrode on the top surface side of the semiconductor chip 4b is electrically connected to the control terminal 10 via a connection member such as the bonding wire 9c. Note that a connection member such as a lead frame (a lead terminal) may be used instead of the bonding wires 9a to 9c.

A sealing resin 7 sealing the semiconductor chips 4a and 4b is provided on the top surface side of the insulating plate 1. The sealing resin 7 has a function to prevent troubles caused by environmental factors such as foreign substance from outside the semiconductor chips 4a and 4b, mechanical external force, and water to improve product reliability. The sealing resin 7 is made of thermosetting resin such as thermosetting silicone gel or epoxy based resin, for example.

A sealing resin frame (case) 8 is provided to surround respective outer peripheries of the sealing resin 7 and the insulating plate 1. FIG. 1 illustrates a case where the top surface of the case 8 is placed above the top surface of the sealing resin 7, but the top surface of the case 8 may be placed at generally the same position as the top surface of the sealing resin 7. Further, FIG. 1 illustrates a case where the bottom surface of the case 8 is placed above the bottom surface of the sealing resin 7, but the bottom surface of the case 8 may be placed at generally the same position as the bottom surface of the sealing resin 7 or may be placed below the bottom surface of the sealing resin 7.

The case 8 is made of resin such as polyphenylene sulfite (PPS), polybutylene terephthalate (PBT), or liquid crystalline polymer (LCP), for example. The case 8 has a function to form a dam to prevent resin from flowing outside when the sealing resin 7 is molded. Furthermore, the case 8 has a function to stabilize an outer shape or secure the strength of the device. When the semiconductor device has a configuration including the case 8, the degree of freedom of extracting an external terminal of the device increases, so that the nut 5a can be taken out of the device from its top surface. Note that the case 8 may not be necessarily provided. For example, the semiconductor device according to the first embodiment may have a caseless configuration including no case 8, and the sealing resin 7 may be formed by injection molding, transfer molding, compression molding, or the like.

A lower portion of the control terminal 10 is embedded in the sealing resin 7. An upper portion of the control terminal 10 is exposed from the top surface of the sealing resin 7 to project upward from (above) the top surface of the sealing resin 7. The control terminal 10 may project from the side surface of the case 8.

FIG. 2 illustrates, in an enlarged manner, a section of a region A surrounding the nut 5a schematically illustrated in FIG. 1 by a broken line. As illustrated in FIG. 1 and FIG. 2, a lower portion of the nut 5a is embedded in the sealing resin 7. An upper portion of the nut 5a is exposed from the top surface of the sealing resin 7 and projects above the top surface of the sealing resin 7 and the top surface of the case 8 such that the upper portion of the nut 5a makes contact with the bottom surface of the main wiring 11. Hereby, it is possible to prevent the sealing resin 7 and the case 8 from interfering with the main wiring 11 when the screw 6a is fastened with the nut 5a to fix the main wiring 11. The main wiring 11 is distanced from the top surface of the case 8 by a predetermined distance d1.

As illustrated in FIG. 2, the screw 6a includes a head 61a and a shank 62a connected to the head 61a. The bottom surface of the head 61a makes contact with the top surface of the main wiring 11. The shank 62a is inserted into a threaded hole 51a of the nut 5a. It is preferable that the shank 62a have a length 11 that is less than a total thickness (t1+t2) of a thickness t1 of the main wiring 11 and a thickness t2 of the nut 5a. Hereby, it is possible to prevent the shank 62a from reaching the insulated circuit board (1, 2a to 2d) and damaging the insulated circuit board (1, 2a to 2d) when the screw 6a is fastened with the nut 5a. Note that the length 11 of the shank 62a may be equal to or more than the total thickness (t1+t2). In this case, a spacer such as a washer is sandwiched between the head 61a and the main wiring 11, for example, so that it is possible to prevent the shank 62a from reaching the insulated circuit board (1, 2a to 2d) when the screw 6a is fastened with the nut 5a.

### <Manufacturing Method of Semiconductor Device>

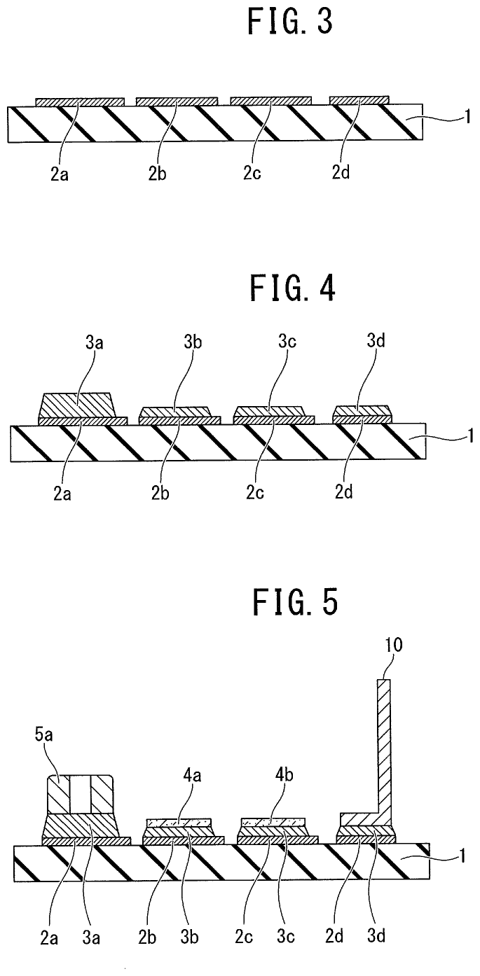

Next, an example of a manufacturing method for manufacturing the semiconductor device according to the first embodiment will be described. First, as illustrated in FIG. 3, the insulated circuit board (1, 2a to 2d) including the insulating plate 1 and the conductive layers 2a to 2d provided on the top surface side of the insulating plate 1 is prepared. Then, as illustrated in FIG. 4, the bonding layers 3a to 3d are formed on respective top surface sides of the conductive layers 2a to 2d by printing, dispensing, or the like.

Subsequently, as illustrated in FIG. 5, the nut 5a is joined to the top surface side of the conductive layer 2a via the bonding layer 3a. Further, the semiconductor chip 4a is joined to the top surface side of the conductive layer 2b via the bonding layer 3b. Also, the semiconductor chip 4b is joined to the top surface side of the conductive layer 2c via the bonding layer 3c. Further, the control terminal 10 is joined to the top surface side of the conductive layer 2d via the bonding layer 3d.

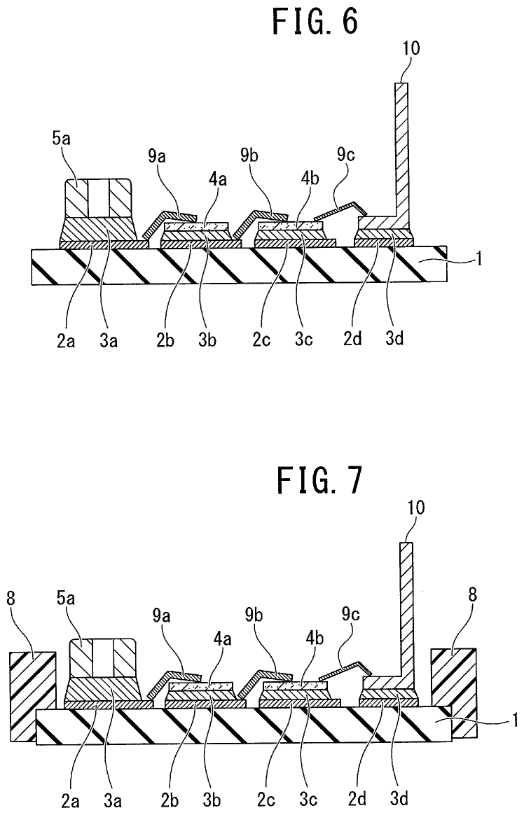

Subsequently, as illustrated in FIG. 6, the emitter electrode on the top surface side of the semiconductor chip 4a is connected to the conductive layer 2a by the bonding wire 9a. Further, the emitter electrode on the top surface side of the semiconductor chip 4b is connected to the conductive layer 2b by the bonding wire 9b. Also, the gate electrode on the top surface side of the semiconductor chip 4b is connected to the control terminal 10 by the bonding wire 9c.

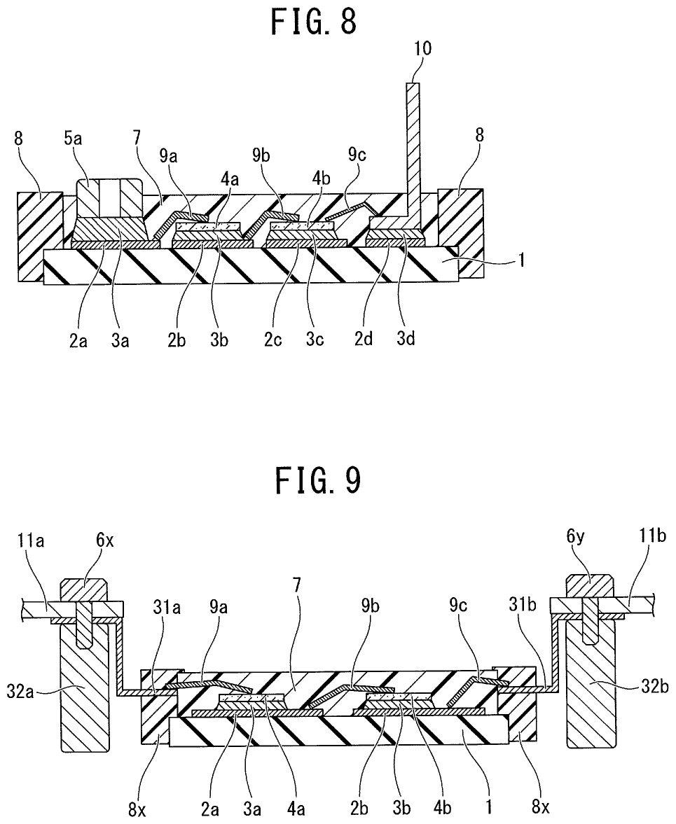

Subsequently, as illustrated in FIG. 7, the case 8 is bonded by an adhesive or the like to surround the outer periphery of the insulated circuit board (1, 2a to 2d). Subsequently, as illustrated in FIG. 8, resin is potted inside the case 8 to form the sealing resin 7 sealing the semiconductor chips 4a and 4b. By adjusting the amount of resin to be potted, the upper portion of the nut 5a can be surely exposed from the top surface of the sealing resin 7. As a result, the semiconductor device according to the first embodiment is completed.

In a conventional semiconductor device, connection with an external circuit is made by fastening outside a case or via an insert component, and therefore, it is difficult to downsize the conventional semiconductor device, a fastener component such as a terminal block is required, or it takes cost to perform insert molding.

The following describes a semiconductor device according to a first comparative example. The semiconductor device according to the first comparative example is different from the semiconductor device according to the first embodiment illustrated in FIG. 1 in that, as illustrated in FIG. 9, external terminals 31a and 31b are attached to a case 8x and project from the side surface of the case 8x. The external terminals 31a and 31b bend in a Z-shape and extend on top surfaces of terminal blocks 32a and 32b. Screws 6x and 6y are fastened to the terminal blocks 32a and 32b, so that the external terminals 31a and 31b and fixed and are electrically connected to main wirings 11a and 11b. In the case of the semiconductor device according to the first comparative example, a module itself can be downsized, but wiring lengths to the main wirings 11a and 11b are long, so that a system is upsized.

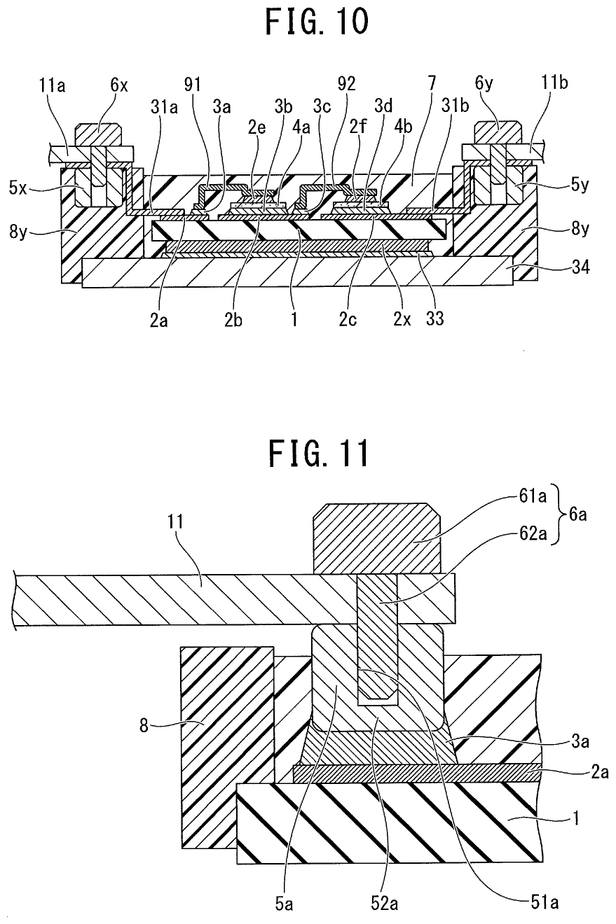

The following describes a semiconductor device according to a second comparative example. The semiconductor device according to the second comparative example is different from the semiconductor device according to the first embodiment illustrated in FIG. 1 in that, as illustrated in FIG. 10, an insulated circuit board (1, 2a to 2c, 2x) is a DCB substrate, a conductive layer 2x is provided on the bottom surface side of the insulating plate 1, and a cooling plate (base) 34 is provided on the bottom surface side of the conductive layer 2x via a bonding layer 33 such as a thermal compound.

Furthermore, the semiconductor device according to the second comparative example is different from the semiconductor device according to the first embodiment illustrated in FIG. 1 in that the external terminals 31a and 31b are attached to a case 8y and extend on the top surface of the case 8y, as illustrated in FIG. 10. Nuts 5x and 5y are embedded in the case 8y. When screws 6x and 6y are fastened with the nuts 5x and 5y, the external terminals 31a and 31b are fixed and electrically connected to the main wirings 11a and 11b. In the case of the semiconductor device according to the second comparative example, a module itself is upsized, and it takes cost to form the case 8y in which the nuts 5x and 5y are embedded.

In contrast, in the case of the semiconductor device according to the first embodiment, as illustrated in FIG. 1 and FIG. 2, the nut 5a as an external terminal having a function of electric connection with an external circuit and a fastening function is incorporated, and the upper portion of the nut 5a is provided to project upward from (above) the top surface of the sealing resin 7. Hereby, the main wiring 11 can be fixed by fastening the screw 6a with the nut 5a above the sealing resin 7. Accordingly, the wiring length required to be connected to the main wiring 11 is shortened, so that the semiconductor device can be downsized.

### Second Embodiment

The overall configuration of a semiconductor device according to a second embodiment is generally the same as the configuration of the semiconductor device according to the first embodiment illustrated in FIG. 1. FIG. 11 illustrates a cross-section of the semiconductor device according to the second embodiment which corresponds to the region A illustrated in FIG. 1. As illustrated in FIG. 11, the semiconductor device according to the second embodiment is different from the semiconductor device according to the first embodiment illustrated in FIG. 2 in that a cover portion 52a for covering one side of the nut 5a as the external terminal is provided, and no threaded hole 51a is formed. The nut 5a may be constituted by a cap nut, for example. The other configuration of the semiconductor device according to the second embodiment is substantially the same as that of the semiconductor device according to the first embodiment, and overlapping explanations are not repeated below.

In the semiconductor device according to the second embodiment, the upper portion of the nut 5a as the external terminal is provided to project upward from (above) the top surface of the sealing resin 7. Hereby, when the screw 6a is fastened with the nut 5a above the sealing resin 7, the main wiring 11 can be fixed. Accordingly, the wiring length required to be connected to the main wiring 11 is shortened, so that the semiconductor device can be downsized.

Furthermore, there is such a case where the bonding layer 3a may enter the threaded hole 51 of the nut 5a by surface tension or the like and disturb the fastening between the nut 5a and the screw 6a. For example, in a case where the bonding layer 3a is made of solder, at the time of joining by the bonding layer 3a, the bonding layer 3a may swell into the threaded hole 51 of the nut 5a due to wetting. In the meantime, the semiconductor device according to the second embodiment includes the cover portion 52a for covering one side of the nut 5a, and therefore, it is possible to prevent the bonding layer 3a from entering the threaded hole 51 of the nut 5a.

### Third Embodiment

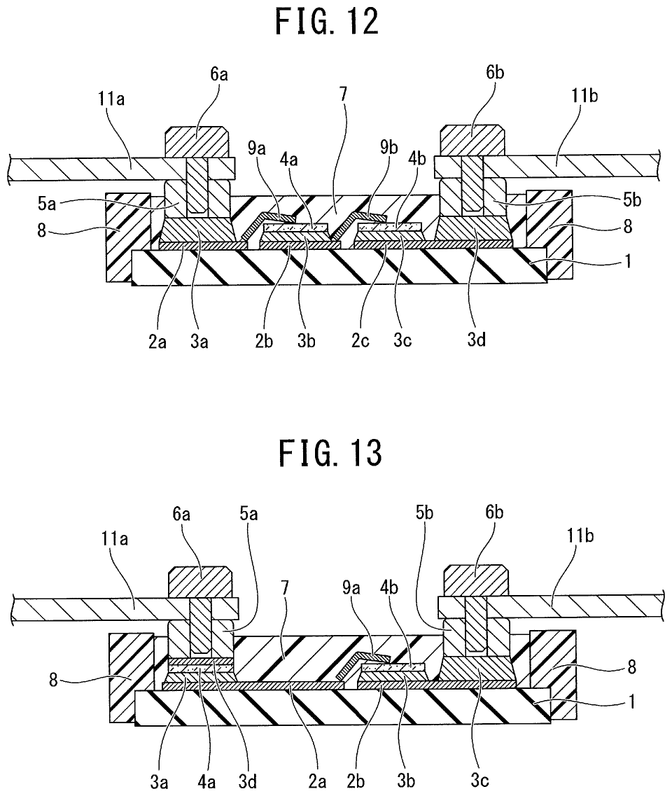

A semiconductor device according to a third embodiment is different from the semiconductor device according to the first embodiment illustrated in FIG. 1 in that a plurality of nuts 5a and 5b is provided as external terminals electrically connected to a plurality of main wirings 11a and 11b as illustrated in FIG. 12. The nut 5a is provided on the top surface side of the conductive layer 2a via the bonding layer 3a. When the screw 6a is fastened with the nut 5a, the main wiring 11a is fixed. The nut 5b is provided on the top surface side of the conductive layer 2c via the bonding layer 3d such that the nut 5b is distanced from the semiconductor chip 4b. When a screw 6b is fastened with the nut 5b, the main wiring 11b is fixed. The other configuration of the semiconductor device according to the third embodiment is substantially the same as that of the semiconductor device according to the first embodiment, and overlapping explanations are not repeated below.

In the case of the semiconductor device according to the third embodiment, respective upper portions of the nuts 5a and 5b as the external terminals are provided to project upward from (above) the top surface of the sealing resin 7. Hereby, when the screws 6a and 6b are fastened with the nuts 5a and 5b above the sealing resin 7, the main wirings 11a and 11b can be fixed. This shortens respective wiring lengths required to be connected to the main wirings 11a and 11b, so that the semiconductor device can be downsized.

### Fourth Embodiment

A semiconductor device according to a fourth embodiment is the same as the semiconductor device according to the third embodiment illustrated in FIG. 12 in that the plurality of nuts 5a and 5b is provided as external terminals electrically connected to the plurality of main wirings 11a and 11b as illustrated in FIG. 13. However, the semiconductor device according to the fourth embodiment is different from the semiconductor device according to the third embodiment illustrated in FIG. 12 in that the nut 5a is provided on the top surface side of the semiconductor chip 4a as illustrated in FIG. 13.

The nut 5a is provided on the top surface side of the semiconductor chip 4a via the bonding layer 3d made of solder, a conductive adhesive, a sintered material, or the like. FIG. 13 illustrates a case where the plurality of nuts 5a and 5b has generally the same thickness. The plurality of nuts 5a and 5b may have different thicknesses, and, for example, the thickness of the nut 5a may be thinner than the thickness of the nut 5b. The other configuration of the semiconductor device according to the fourth embodiment is substantially the same as that of the semiconductor device according to the third embodiment illustrated in FIG. 12, and overlapping explanations are not repeated below.

In the semiconductor device according to the fourth embodiment, respective upper portions of the nuts 5a and 5b as the external terminals are provided to project upward from (above) the top surface of the sealing resin 7. Hereby, when the screws 6a and 6b are fastened with the nuts 5a and 5b above the sealing resin 7, the main wirings 11a and 11b can be fixed. This shortens respective wiring lengths required to be connected to the main wirings 11a and 11b, so that the semiconductor device can be downsized.

Further, in the case of the semiconductor device according to the fourth embodiment, the nut 5a is provided on the top surface side of the semiconductor chip 4a, so that the area to place the nut 5a can be reduced, thereby making it possible to further downsize the semiconductor device.

### Fifth Embodiment

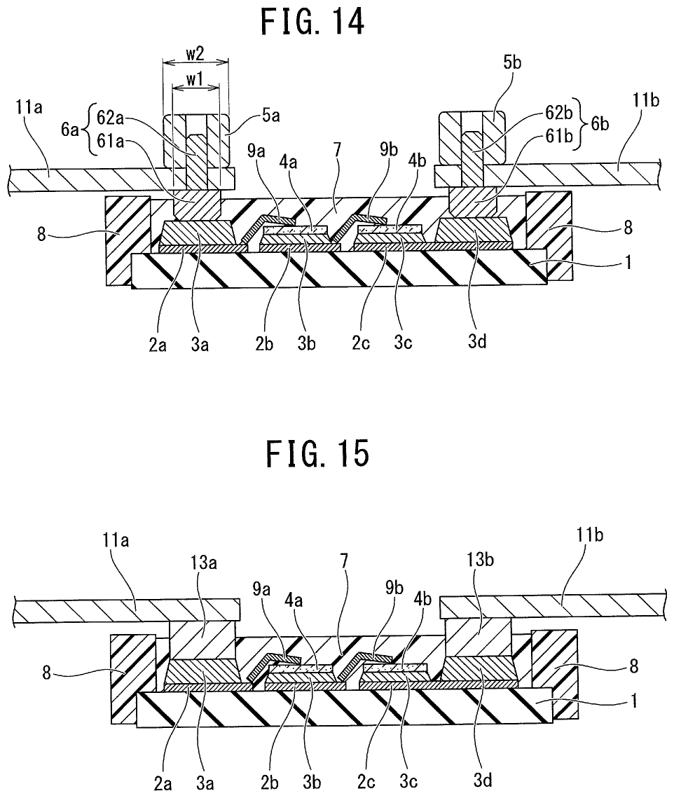

A semiconductor device according to a fifth embodiment is the same as the semiconductor device according to the third embodiment illustrated in FIG. 12 in that external terminals electrically connected to the plurality of main wirings 11a and 11b are provided as illustrated in FIG. 14. However, the semiconductor device according to the fifth embodiment is different from the semiconductor device according to the third embodiment illustrated in FIG. 12 in that the screws 6a and 6b are provided as the external terminals as illustrated in FIG. 14.

The screw 6a includes the head 61a and the shank 62a connected to the head 61a such that a tip end of the shank 62a faces upward. The bottom surface of the head 61a is joined to the conductive layer 2a via the bonding layer 3a. A lower portion of the head 61a is embedded in the sealing resin 7. An upper portion of the head 61a projects from the top surface of the sealing resin 7 and makes contact with the bottom surface of the main wiring 11a. When the nut 5a is fastened with the screw 6a, the main wiring 11a is fixed.

The screw 6b includes a head 61b and a shank 62b connected to the head 61b such that a tip end of the shank 62b faces upward. The bottom surface of the head 61b is joined to the conductive layer 2c via the bonding layer 3d. A lower portion of the head 61b is embedded in the sealing resin 7. An upper portion of the head 61b projects from the top surface of the sealing resin 7 and makes contact with the bottom surface of the main wiring 11b. When the screw 6b is fastened with the nut 5b, the main wiring 11b is fixed. The other configuration of the semiconductor device according to the fifth embodiment is substantially the same as that of the semiconductor device according to the third embodiment illustrated in FIG. 12, and overlapping explanations are not repeated below.

In the case of the semiconductor device according to the fifth embodiment, the screws 6a and 6b as the external terminals are incorporated, and respective upper portions of the screws 6a and 6b are provided to project upward from (above) the top surface of the sealing resin 7. Hereby, when the screws 6a and 6b are fastened with the nuts 5a and 5b above the sealing resin 7, the main wirings 11a and 11b can be fixed. This shortens respective wiring lengths required to be connected to the main wirings 11a and 11b, so that the semiconductor device can be downsized.

Further, in the case of the semiconductor device according to the fifth embodiment, the screws 6a and 6b are provided as the external terminals, and therefore, in comparison with the case where the external terminals are nuts, there is no concern that the bonding layers 3a and 3b joined to the nuts enter threaded holes of the nuts.

Further, in the case of the semiconductor device according to the fifth embodiment, the screws 6a and 6b are provided as the external terminals, so that the screws 6a and 6b can have a width w1 narrowed than a width w2 of the nuts 5a and 5b. Hereby, respective areas to place the screws 6a and 6b can be reduced, thereby making it possible to further downsize the semiconductor device. Note that the width w1 of the screws 6a and 6b may generally the same as the width w2 of the nuts 5a and 5b or may be wider than the width w2 of the nuts 5a and 5b.

### Sixth Embodiment

A semiconductor device according to a sixth embodiment is the same as the semiconductor device according to the third embodiment illustrated in FIG. 12 in that external terminals connected to the plurality of main wirings 11a and 11b are provided as illustrated in FIG. 15. However, the semiconductor device according to the sixth embodiment is different from the semiconductor device according to the semiconductor device according to the third embodiment illustrated in FIG. 12 in that terminal blocks (conductive blocks) 13a and 13b are provided as external terminals as illustrated in FIG. 15.

Respective lower portions of the terminal blocks 13a and 13b are embedded in the sealing resin 7. Respective upper portions of the terminal blocks 13a and 13b project from the top surface of the sealing resin 7. The terminal block 13a is joined to the main wiring 11a directly by welding such as laser welding or via a bonding layer (not illustrated) made of solder, a conductive adhesive, a sintered material, or the like. The terminal block 13b is joined to the main wiring 11b directly by welding such as laser welding or via a bonding layer (not illustrated) made of solder, a conductive adhesive, a sintered material, or the like.

The terminal blocks 13a and 13b are made of metal such as copper (Cu), Cu alloy, aluminum (Al), or Al alloy, for example. It is preferable that the terminal blocks 13a and 13b be made of a material having a high conductivity. It is preferable that respective surfaces of the terminal blocks 13a and 13b be plated with nickel (Ni), tin (Sn), or the like, for example, so that soldering or welding is easily performable.

Respective shapes of the terminal blocks 13a and 13b are not limited in particular. The terminal blocks 13a and 13b may have a generally rectangular solid shape or a generally disk shape, for example, or may be constituted by nuts having a threaded hole. The other configuration of the semiconductor device according to the sixth embodiment is substantially the same as that of the semiconductor device according to the third embodiment illustrated in FIG. 12, and overlapping explanations are not repeated below.

In the case of the semiconductor device according to the sixth embodiment, the terminal blocks 13a and 13b as the external terminals are incorporated, and respective upper portions of the terminal blocks 13a and 13b are provided to project upward from (above) the top surface of the sealing resin 7. Hereby, the main wirings 11a and 11b can be fixed to the terminal blocks 13a and 13b above the sealing resin 7. This shortens respective wiring lengths required to be connected to the main wirings 11a and 11b, so that the semiconductor device can be downsized.

### Seventh Embodiment

The following deals with a case where a semiconductor device according to a seventh embodiment is applied to a control circuit (an exciter) for controlling a separately excited synchronous machine (SESM). Note that the semiconductor device according to the seventh embodiment may be applied to a control circuit of a switched reluctance motor.

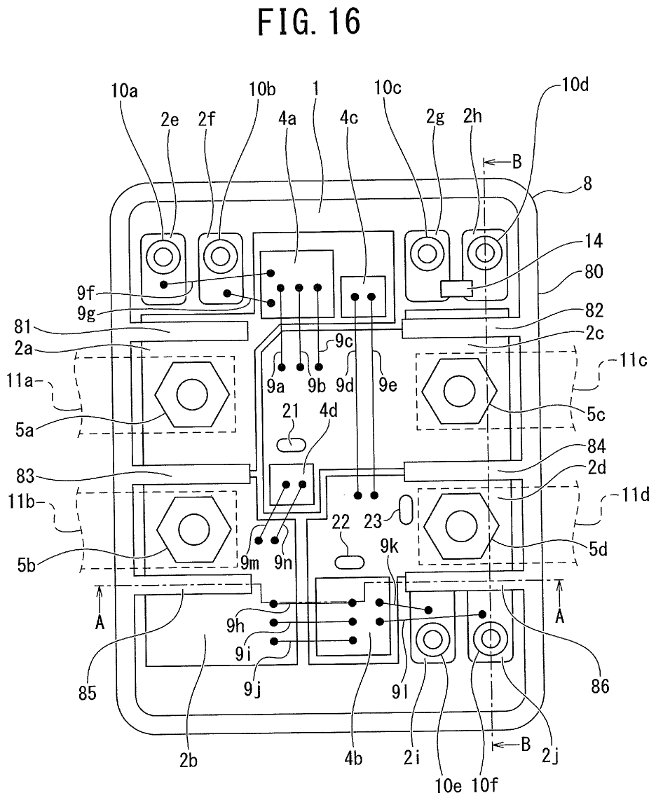

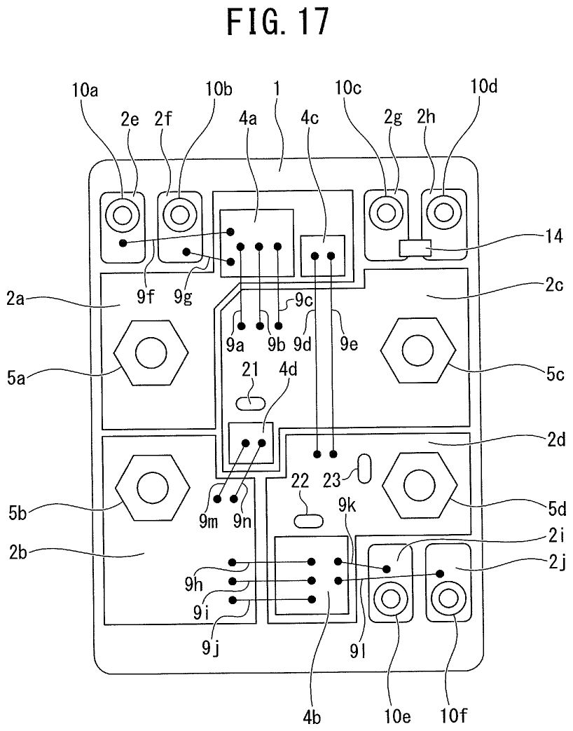

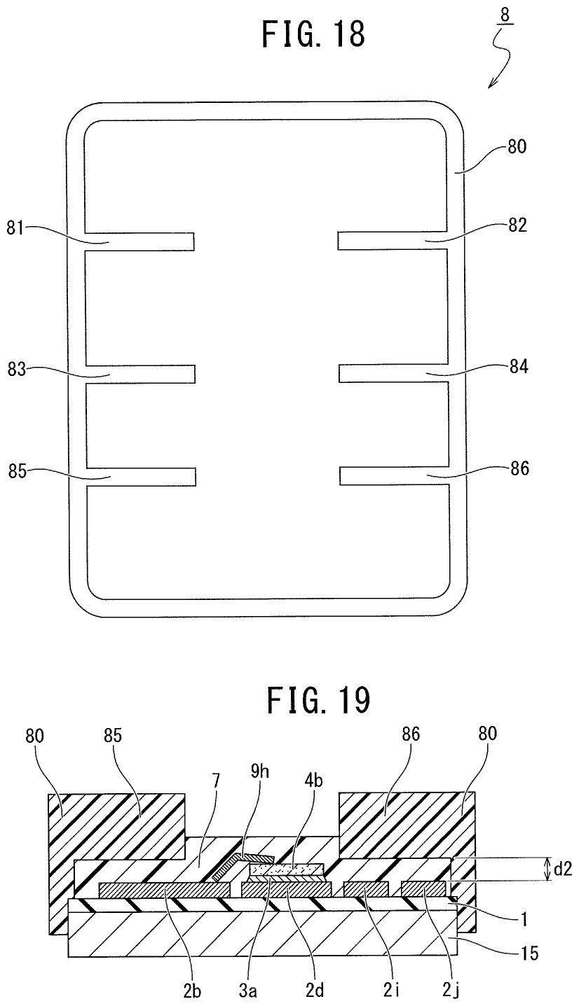

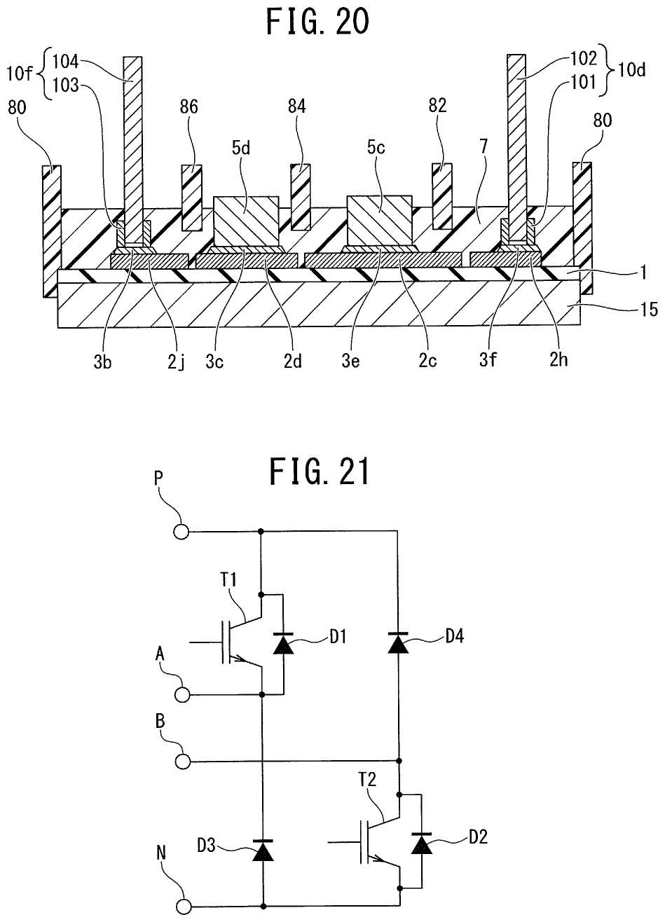

FIG. 16 is a plan view of the semiconductor device according to the seventh embodiment. In FIG. 16, the sealing resin 7 is omitted. FIG. 17 is a plan view in which the case 8 is omitted in FIG. 16, and FIG. 18 is a plan view illustrating only the case 8 in FIG. 16. FIG. 19 illustrates a cross-section viewed from a direction of A-A in FIG. 16. FIG. 20 illustrates a cross-section viewed from a direction of B-B in FIG. 16.

As illustrated in FIG. 16 to FIG. 20, an insulated circuit board (1, 2a to 2j, 15) includes the insulating plate 1, conductive layers 2a to 2j provided on the top surface side of the insulating plate 1, and a heat dissipation plate 15 provided on the bottom surface side of the insulating plate 1. The insulating plate 1 is made of a resin insulating layer, for example. The conductive layers 2a to 2j are made of copper (Cu) or aluminum (Al), for example. The heat dissipation plate 15 is made of copper (Cu) or aluminum (Al), for example.

As illustrated in FIG. 16 and FIG. 17, the nut 5a and the semiconductor chip 4a and 4c are provided on the top surface side of the conductive layer 2a to be distanced from each other. The semiconductor chip 4a is constituted by a reverse conducting IGBT (RC-IGBT) made of silicon (Si), for example. The emitter electrode on the top surface side of the semiconductor chip 4a is electrically connected to the conductive layer 2c via bonding wires 9a to 9c. The gate electrode on the top surface side of the semiconductor chip 4a is electrically connected to the conductive layer 2e via a bonding wire 9f. An emitter electrode on the top surface side of the semiconductor chip 4a is electrically connected to the conductive layer 2f via a bonding wire 9g.

A semiconductor chip 4c is constituted by a Schottky barrier diode made of silicon carbide (SiC), for example. A cathode electrode on the bottom surface side of the semiconductor chip 4c is joined to the conductive layer 2a. An anode electrode on the top surface side of the semiconductor chip 4c is electrically connected to the conductive layer 2d via bonding wires 9d and 9e.

The nut 5b is provided on the top surface side of the conductive layer 2b. The position of the nut 5b is substantially the same as the position of the nut 5a in the longitudinal direction (the up-down direction in FIG. 16 and FIG. 17) of a rectangular shape formed by a plane pattern of the insulating plate 1.

The conductive layer 2c has a through-hole 21. A nut 5c and a semiconductor chip 4d are provided on the top surface side of the conductive layer 2c. The semiconductor chip 4d is constituted by a Schottky barrier diode made of silicon carbide (SiC), for example. An anode electrode on the top surface side of the semiconductor chip 4d is electrically connected to the conductive layer 2b via bonding wires 9m and 9n. The position of the nut 5c is generally the same as the position of the nut 5a in the short direction (the right-left direction in FIG. 16 and FIG. 17) of the rectangular shape formed by the plane pattern of the insulating plate 1.

The conductive layer 2d has through-holes 22 and 23. A nut 5d and a semiconductor chip 4b are provided on the top surface side of the conductive layer 2d. The position of the nut 5d is generally the same as the position of the nut 5b in the short direction (the right-left direction in FIG. 16 and FIG. 17) of the rectangular shape formed by the plane pattern of the insulating plate 1, and the position of the nut 5d is generally the same as the position of the nut 5c in the longitudinal direction (the up-down direction in FIG. 16 and FIG. 17) of the rectangular shape formed by the plane pattern of the insulating plate 1.

The semiconductor chip 4b is constituted by a reverse conducting IGBT (RC-IGBT) made of silicon (Si), for example. The emitter electrode on the top surface side of the semiconductor chip 4b is electrically connected to the conductive layer 2b via bonding wires 9h to 9j. The emitter electrode on the top surface side of the semiconductor chip 4b is electrically connected to the conductive layer 2i via a bonding wire 9k. The gate electrode on the top surface side of the semiconductor chip 4b is electrically connected to the conductive layer 2j via a bonding wire 9l.

A control terminal 10a as a gate terminal is provided on the top surface side of the conductive layer 2e. The control terminal 10a is electrically connected to the gate electrode of the semiconductor chip 4a via the conductive layer 2e and the bonding wire 9f.

A control terminal 10b as an auxiliary emitter terminal is provided on the top surface side of the conductive layer 2f. The control terminal 10b is electrically connected to the emitter electrode of the semiconductor chip 4a via the conductive layer 2f and the bonding wire 9g.

A portion of a diode 14 for temperature measurement is provided on the top surface side of the conductive layer 2g. Furthermore, a control terminal 10c as a terminal for temperature measurement is provided on the top surface side of the conductive layer 2g. The control terminal 10c is electrically connected to one of an anode electrode and a cathode electrode of the diode 14 for temperature measurement via the conductive layer 2g.

Another portion of the diode 14 for temperature measurement is provided on the top surface side of the conductive layer 2h. Furthermore, a control terminal 10d as a terminal for temperature measurement is provided on the top surface side of the conductive layer 2h. The control terminal 10d is electrically connected to the other one of the anode electrode and the cathode electrode of the diode 14 for temperature measurement via the conductive layer 2h.

A control terminal 10e as an auxiliary emitter terminal is provided on the top surface side of the conductive layer 2i. The control terminal 10e is electrically connected to the emitter electrode of the semiconductor chip 4b via the conductive layer 2i and the bonding wire 9k.

A control terminal 10f as a gate terminal is provided on the top surface side of the conductive layer 2j. The control terminal 10f is electrically connected to the gate electrode of the semiconductor chip 4b via the conductive layer 2j and the bonding wire 9l.

FIG. 16 schematically illustrates, by broken lines, main wirings 11a to 11d electrically connected to the nuts 5a to 5d at the time of the use of the semiconductor device according to the seventh embodiment. When a screw (not illustrated) is fastened with the nut 5a, the main wiring 11a is fixed. When a screw (not illustrated) is fastened with the nut 5b, the main wiring 11b is fixed. When a screw (not illustrated) is fastened with the nut 5c, the main wiring 11c is fixed. When a screw (not illustrated) is fastened with the nut 5d, the main wiring 11d is fixed. The main wirings 11a and 11b are distanced from each other and extend in parallel. The main wirings 11c and 11d are distanced from each other and extend in parallel.

As illustrated in FIG. 19, the semiconductor chip 4b is joined to the conductive layer 2d via the bonding layer 3a. As illustrated in FIG. 20, the nut 5c is joined to the conductive layer 2c via a bonding layer 3e. The nut 5d is joined to the conductive layer 2d via the bonding layer 3c.

As illustrated in FIG. 20, the control terminal 10d includes a support portion (a sleeve) 101, and a terminal portion (a pin) 102 supported by the sleeve 101. The sleeve 101 is joined to the conductive layer 2h via a bonding layer 3f. The pin 102 is fitted to the sleeve 101 by pressing to be fixed to the sleeve 101 and extends upward. The control terminal 10f includes a support portion (a sleeve) 103, and a terminal portion (a pin) 104 supported by the sleeve 103. The pin 104 is fitted to the sleeve 103 by pressing to be fixed to the sleeve 103 and extends upward. The control terminals 10a to 10c, and 10e illustrated in FIG. 16 and FIG. 18 also have configurations similar to those of the control terminals 10d and 10f illustrated in FIG. 20. Note that the configurations of the control terminals 10a to 10f is not particularly limited. The control terminals 10a to 10f may be terminals joined by solder or the like without the use of the sleeves, for example.

As illustrated in FIG. 16 and FIG. 18, the case 8 is provided to surround the outer periphery of the insulating plate 1. The case 8 includes a frame portion 80 surrounding the outer periphery of the insulating plate 1, and wall portions 81 to 86 extending (overhanging) from the frame portion 80 into the frame portion 80. A lower end of the frame portion 80 is bonded to the insulated circuit board (1, 2a to 2j, 15) by an adhesive such as epoxy resin.

The wall portions 81 to 86 are formed integrally with the frame portion 80. The wall portions 81 to 86 have a function to secure a creepage distance for insulation between different potentials. As illustrated in FIG. 16, the wall portion 81 extends above the conductive layer 2a and is placed between the control terminals 10a and 10b and the nut 5a. The wall portion 81 secures a creepage distance for insulation between the control terminals 10a and 10b and the nut 5a. The wall portion 82 extends above the conductive layer 2c and is placed between the control terminals 10c and 10d and the nut 5c. The wall portion 82 secures a creepage distance for insulation between the control terminals 10c and 10d and the nut 5c. An end portion of the wall portion 81 and an end portion of the wall portion 82 face each other.

The wall portion 83 extends above a position between the conductive layer 2a and the conductive layer 2b and is placed between the nut 5a and the nut 5b. The wall portion 83 secures a creepage distance for insulation between the nut 5a and the nut 5b. The wall portion 84 extends above a position between the conductive layer 2c and the conductive layer 2d and is placed between the nut 5c and the nut 5d. The wall portion 84 secures a creepage distance for insulation between the nut 5c and the nut 5d. An end portion of the wall portion 83 and an end portion of the wall portion 84 face each other.

The wall portion 85 extends above the conductive layer 2b and is placed to sandwich the nut 5b between the wall portion 85 and the wall portion 83. The wall portion 86 extends above a position between the conductive layer 2d and the conductive layers 2i and 2j and is placed between the nut 5d and the control terminals 10e and 10f. The wall portion 86 secures a creepage distance for insulation between the nut 5d and the control terminals 10e and 10f. An end portion of the wall portion 85 and an end portion of the wall portion 86 face each other.

As illustrated in FIG. 19 and FIG. 20, respective lower portions of the wall portions 82, and 84 to 86 are embedded in the sealing resin 7. Respective lower ends of the wall portions 82, and 84 to 86 are set at a position distanced from the insulated circuit board (1, 2a to 2j, 15) by a predetermined distance d2 so as not to disturb an element placement area on the top surface side of the insulated circuit board (1, 2a to 2j, 15). Respective lower ends of the wall portions 81 and 83 illustrated in FIG. 16 and FIG. 19 are also set at a position distanced by the predetermined distance d2 similarly to the wall portions 82, and 84 to 86.

As illustrated in FIG. 19 and FIG. 20, respective upper portions of the wall portions 82, and 84 to 86 have a projection projecting upward from (above) the top surface of the sealing resin 7. Since the wall portions 82, and 84 to 86 have a projection, it is possible to secure an insulation distance between different potentials. The wall portions 81 and 83 illustrated in FIG. 16 and FIG. 19 also have a projection projecting upward from (above) the top surface of the sealing resin 7, similarly to the wall portions 82, and 84 to 86 illustrated in FIG. 19 and FIG. 20.

The other configuration of the semiconductor device according to the seventh embodiment is substantially the same as that of the semiconductor device according to the first embodiment, and overlapping explanations are not repeated below.

### <Circuitry of Semiconductor Device>

FIG. 21 illustrates an equivalent circuit of the semiconductor device according to the seventh embodiment. As illustrated in FIG. 21, the semiconductor device according to the seventh embodiment includes a positive terminal P, a negative terminal N, an output terminal A, and an output terminal B.

A collector of a transistor T1 and a cathode of a diode D4 are connected to the positive terminal P. A body diode D1 serving as a freewheeling diode (FWD) is connected to the transistor T1 in antiparallel and incorporated in the transistor T1. The output terminal A and a cathode of a diode D3 are connected to an emitter of the transistor T1.

An emitter of a transistor T2 and an anode of a diode D3 are connected to the negative terminal N. A body diode D2 serving as a freewheeling diode (FWD) is connected to the transistor T2 in antiparallel and incorporated in the transistor T2. The output terminal B and an anode of a diode D4 are connected to a collector of the transistor T2.

The positive terminal P, the negative terminal N, the output terminal A, and the output terminal B illustrated in FIG. 21 correspond to the main wiring 11a, the main wiring 11b, the main wiring 11c, and the main wiring 11d schematically illustrated by broken lines in FIG. 16. The transistor T1 and the body diode D1 illustrated in FIG. 21 correspond to the semiconductor chip 4a illustrated in FIG. 16. The transistor T2 and the body diode D2 illustrated in FIG. 21 correspond to the semiconductor chip 4b illustrated in FIG. 16. The diode D3 illustrated in FIG. 21 corresponds to the semiconductor chip 4d illustrated in FIG. 16. The diode D4 illustrated in FIG. 21 corresponds to the semiconductor chip 4c illustrated in FIG. 16.

In the case of the semiconductor device according to the seventh embodiment, the nuts 5a to 5d are incorporated, and respective upper portions of the nuts 5a to 5d are provided to project upward from (above) the top surface of the sealing resin 7. Hereby, when respective screws are fastened with the nuts 5a to 5d above the sealing resin 7, the main wirings 11a to 11d can be fixed. This shortens respective wiring lengths required to be connected to the main wirings 11a to 11d, so that the semiconductor device can be downsized.

Furthermore, since the case 8 includes the wall portions 81 to 86, the creepage distances for insulation between different potentials including the nuts 5a to 5d can be secured.

### Other Embodiments

As described above, the invention has been described according to the first to seventh embodiments, but it should not be understood that the description and drawings implementing a portion of this disclosure limit the invention. Various alternative embodiments of the present invention, examples, and operational techniques will be apparent to those skilled in the art from this disclosure.

For example, the fourth embodiment has been described a case where the nut 5a is provided as an external terminal on the top surface side of the semiconductor chip 4a as illustrated in FIG. 13, but the screw 6a as illustrated in FIG. 14 may be provided instead of the nut 5a.

Further, the seventh embodiment has described a case where the semiconductor device is applied to an exciter, but the semiconductor device is naturally applicable to devices other than the exciter. For example, the semiconductor device is also applicable to an inverter circuit of a three-phase motor.

Further, the seventh embodiment has described a case where the nuts 5a to 5d are provided each as one external terminal for a corresponding one of the main wirings 11a to 11d, but a plurality of nuts may be provided for each of the main wirings 11a to 11d.

The configurations disclosed in the first to seventh embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
an insulated circuit board including an insulating plate and a conductive layer provided on a top surface side of the insulating plate;
a semiconductor chip provided on a top surface side of the conductive layer;
a sealing resin sealing the semiconductor chip;
a case provided to surround an outer periphery of the sealing resin and placing above the top surface of the sealing resin; and
an external terminal electrically connected to the semiconductor chip and having a lower portion embedded in the sealing resin and an upper portion projecting above a top surface of the sealing resin and a top surface of the case.

2. The semiconductor device of claim 1, wherein the external terminal is provided on the top surface side of the conductive layer.

3. The semiconductor device of claim 1, wherein the external terminal is provided on a top surface side of the semiconductor chip.

4. The semiconductor device of claim 1, wherein the external terminal is constituted by a nut.

5. The semiconductor device of claim 4, wherein one surface of the nut is closed.

6. The semiconductor device of claim 1, wherein the external terminal is constituted by a screw.

7. The semiconductor device of claim 6, wherein the screw includes
a head having a lower portion embedded in the sealing resin and an upper portion projecting above the top surface of the sealing resin, and
a shank connected to the head and provided above the top surface of the sealing resin.

8. The semiconductor device of claim 1, wherein the external terminal is constituted by a terminal block.

9. The semiconductor device of claim 2, wherein the case includes
a frame portion surrounding the outer periphery of the sealing resin, and
a wall portion extending inwardly from the frame portion.

10. The semiconductor device of claim 9, wherein the wall portion projects above the top surface of the sealing resin.

11. The semiconductor device of claim 1, further comprising a control terminal electrically connected to the semiconductor chip and projecting from the top surface of the sealing resin.
